(19) United States
(12) Patent Application Publication
(10) Pub. No.: US 2023/0223341 A1
(43) Pub. Date: Jul. 13, 2023

(54) LOW VIA RESISTANCE INTERCONNECT STRUCTURE

(71) Applicant: QUALCOMM Incorporated, San Diego, CA (US)

(72) Inventors: Junjing BAO, San Diego, CA (US); John Jianhong Zhu, San Diego, CA (US); Giridhar Nallapati, San Diego, CA (US)

(21) Appl. No.: 17/573,461

(22) Filed: Jan. 11, 2022

(51) Int. Cl. H01L 23/532; H01L 23/528; H01L 21/768; H01L 23/522

(52) U.S. Cl. CPC H01L 23/53238; H01L 23/53266; H01L 23/5283; H01L 23/53223; H01L 21/76846; H01L 21/76879; H01L 23/5226; H01L 21/76831

(57) ABSTRACT

An interconnect structure comprising a low via resistance via structure is disclosed. The via structure comprises a barrier layer on sidewalls and at bottom of the via structure. The interconnect structure also includes a first metal layer. The interconnect structure further includes a second metal layer between the barrier layer at the bottom of the via structure and the first metal layer, wherein the first metal layer and the second metal layer comprise different materials.

### BACKGROUND

### Field

Certain aspects of the present disclosure generally relate to interconnects, and more particularly, to an interconnect structure comprising a low via resistance via structure.

### Background

Computing devices have become increasingly common in modern society. Early computers were the size of a room and employed vacuum tubes to perform basic mathematical calculations. In contrast, modern computing devices provide various complex functions in a relatively small footprint based on integrated circuits (ICs). There is market pressure to provide ever increasing processing options in increasingly small products.

The continued advances in IC functionality in a smaller footprint are stressing manufacturing capabilities. Current IC manufacturing processes rely on lithography to create ICs in the form of a semiconductor die. IC may include an active semiconductor layer fabricated in a front-end-of-line process. The active semiconductor layer may contain various semiconductor devices. IC may also include an interconnect structure formed adjacent to the active semiconductor layer through a back-end-of-line process. The interconnect structure may contain multiple metallization layers each with metal lines disposed in a respective metallization layer to provide connections between different semiconductor devices and external interconnects. Vertical interconnect accesses (vias) may be disposed between metallization layers to provide connections for the different metallization layers.

### SUMMARY

Certain aspects of the present disclosure provide an interconnect structure of a semiconductor device. The interconnect structure may include a via structure, the via structure comprising a barrier layer on sidewalls and at bottom of the via structure. The interconnect structure may also include a first metal layer. The interconnect structure may further include a second metal layer between the barrier layer at the bottom of the via structure and the first metal layer, wherein the first metal layer and the second metal layer comprise different materials.

Certain aspects of the present disclosure provide a method for fabricating an interconnect structure of a semiconductor device. The method may include forming a via opening on a first metal layer. The method may also include forming a second metal layer at bottom of the via opening. The first metal layer and the second metal layer comprise different materials. The method may also include forming a barrier layer on sidewalls and at the bottom of the via opening, wherein the second metal layer is between the barrier layer at the bottom of the via opening and the first metal layer. The method may further include depositing metal in the via opening.

This summary has outlined the features and embodiments of the present disclosure so that the following detailed description may be better understood. Additional features and embodiments of the present disclosure will be described below. It should be appreciated by those skilled in the art that this disclosure may be readily utilized as a basis for modifying or designing other equivalent structures for carrying out the same purposes of the present disclosure. It should also be realized by those skilled in the art that such equivalent constructions do not depart from the teachings of the present disclosure as set forth in the appended claims. The features, which are believed to be characteristic of the present disclosure, both as to its organization and method of operation, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

FIG. 1 illustrates an exemplary interconnect structure of a semiconductor device comprising a first metal layer and a second metal layer connected by a via structure with low via resistance in accordance with certain aspects of the present disclosure;

FIGS. 2A-2B illustrate an exemplary fabrication process for the interconnect structure 100 in FIG. 1 in accordance with certain aspects of the present disclosure;

FIG. 3 shows a flow chart illustrating an exemplary fabrication process for the interconnect structure 100 in FIG. 1; and

FIG. 4 is a block diagram showing an exemplary wireless communication system in which an aspect of the present disclosure may be employed.

### DETAILED DESCRIPTION

With reference to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

The detailed description set forth below, in connection with the appended drawings, is intended as a description of various aspects and is not intended to represent the only aspect in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts.

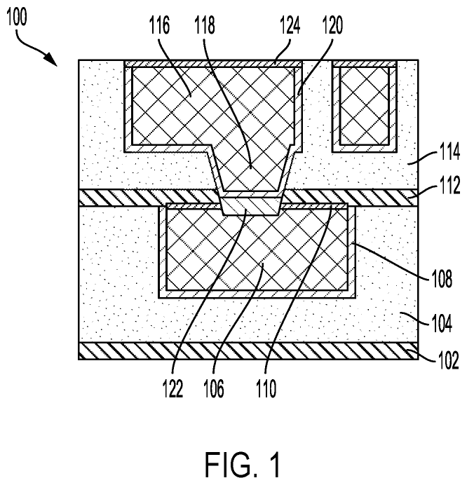

FIG. 1 illustrates an exemplary interconnect structure of a semiconductor device comprising a first metal layer and a second metal layer connected by a via structure with low via resistance in accordance with certain aspects of the present disclosure. An interconnect structure 100 is shown in FIG. 1. The interconnect structure 100 comprises a first etch stop layer 102. As an example, the first etch stop layer 102 may comprise at least one of Silicon Carbon Nitride (SiCN) and Aluminum Nitride (AlN) with Oxygen Doped Carbon (ODC). The interconnect structure 100 also comprises a first dielectric layer 104 on the first etch stop layer 102. As an example, the first dielectric layer 104 may comprise Carbon Doped Silicon Oxide (SiCOH). The interconnect structure 100 also comprises a first metal layer 106 in the first dielectric layer 104. As an example, the first metal layer 106 may comprise Copper (Cu). The interconnect structure 100 also comprises a first barrier layer 108 between the first dielectric layer 104 and the first metal layer 106. As an example, the first barrier layer 108 may comprise a first Tantalum Nitride (TaN) layer between the first dielectric layer 104 and the first metal layer 106 and a first Cobalt (Co) liner between the first TaN layer and the first metal layer 106. The interconnect structure 100 also comprises a first cap layer 110 on the first metal layer 106. As an example, the first cap layer 110 may comprises Co.

The interconnect structure 100 also comprises a second etch stop layer 112 on the first dielectric layer 104 and on the first cap layer 110. As an example, the second etch stop layer 112 may comprise at least one of SiCN and AN with ODC. The interconnect structure 100 also comprises a second dielectric layer 114 on the second etch stop layer 112. As an example, the second dielectric layer 114 may comprise SiCOH. The interconnect structure 100 also comprises a second metal layer 116 and a via structure 118 in the second dielectric layer 114. As an example, the second metal layer 116 may comprise Cu. The via structure 118 is between the first metal layer 106 and the second metal layer 116. The via structure 118 comprises a second barrier layer 120 on sidewalls and at bottom of the via structure 118 and a via metal in the via structure 118. As an example, the via metal may comprise Cu. The second barrier layer 120 is also on sidewalls and at bottom of the second metal layer 116. As an example, the second barrier layer 120 may comprise a second TaN layer between the second dielectric layer 114 and the via metal and between the second dielectric layer 114 and the second metal layer 116 and a second Co liner between the second TaN layer and the via metal and between the second TaN layer and the second metal layer 116 on the sidewalls of the via structure 118 and on the sidewalls and at the bottom of the second metal layer 116. At the bottom of the via structure 118, the second TaN layer may be between the first metal layer 106 and the via metal and the second Co liner may be between the second TaN layer and the via metal.

TaN layers may be formed by Physical Vapor Deposition (PVD) at room temperature. PVD is a non-conformal deposition process. A thickness of PVD TaN layer at the bottom of the via structure 118 would be around twice a thickness of PVD TaN layer on the sidewalls of the via structure 118. Alternatively, TaN layers may be formed by Atomic Layer Deposition (ALD) at around 275° C. ALD is a conformal deposition process. A thickness of ALD TaN layer at the bottom of the via structure 118 would be around the same as a thickness of ALD TaN layer on the sidewalls of the via structure 118. A thickness of TaN layer at the bottom of the via structure 118 would affect via resistance of the via structure 118. A thinner TaN layer at the bottom of the via structure 118 would reduce the via resistance of the via structure 118 and improve performance of the interconnect structure 100. Meanwhile, PVD TaN layer has better adhesion to Co liners compared to ALD TaN layer. Thus, to realize both low via resistance and good adhesion to Co liners, ALD TaN layer could be combined with PVD TaN layer to form the second TaN layer in the second barrier layer 120. For example, the second TaN layer may comprise ALD TaN layer with a thickness of 16 Angstrom (A) and PVD TaN layer with a thickness of 10 A on the sidewalls of the via structure 118. At the bottom of the via structure 118, the second TaN layer may comprise ALD TaN Layer with a thickness of 16 A and PVD TaN layer with a thickness of 20 A. Thus, at the bottom of the via structure 118, the second TaN layer may be around 36 A thick. Meanwhile, if the second TaN layer comprises PVD TaN layer only, with the same TaN layer thickness (26 A) on the sidewalls of the via structure 118, a thickness of the second TaN layer at the bottom of the via structure 118 would be around 52 A, which is thicker compared to 36 A. Therefore, a combination of ALD TaN layer and PVD TaN layer to form the second TaN layer would realize both low via resistance and good adhesion to Co liners. The second TaN layer may comprise an ALD TaN layer with a thickness between 11 A and 21 A between the second dielectric layer 114 and the second Co liner and a PVD TaN layer with a thickness between 5 A and 15 A between the ALD TaN layer and the second Co liner on the sidewalls of the via structure 118. At the bottom of the via structure 118, the ALD TaN layer may be between the first metal layer 106 and the second Co liner and the PVD TaN layer may be between the ALD TaN layer and the second Co liner. The second Co liner may have a thickness between 20 A and 30 A. Because the first TaN layer does not contribute to the via resistance of the via structure 118, the first TaN layer may comprise ALD TaN layer only, PVD TaN layer only, or a combination of ALD TaN layer and PVD TaN layer.

As mentioned above, ALD may be performed around 275° C. This temperature would generate stress at interface between the ALD TaN layer at the bottom of the vias structure 118 and Cu in the first metal layer 106 due to different coefficients of thermal expansion between TaN (3.6×10⁻⁶/K) and Cu (16.5×10⁻⁶/K). The stress generated may lead to voids formed at the interface and increase the via resistance of the via structure 118. To avoid such stress, the interconnect structure 100 also comprises a third metal layer 122 between the ALD TaN layer at the bottom of the via structure 118 and the first metal layer 106. As an example, the third metal layer 122 may comprise a metallic material having a coefficient of thermal expansion less than 7×10⁻⁶/K, such as Tungsten (W), Molybdenum (Mo), Chromium (Cr), Osmium (Os), Zirconium (Zr), Hafnium (Hf), Rhenium (Re), Cerium (Ce), Tantalum (Ta), Ruthenium (Ru), Iridium (Jr), and Praseodymium (Pr). The third metal layer 122 may have a thickness less than 5 nanometer (nm). A top surface of the third metal layer 122 may be coplanar with or below a top surface of the second etch stop layer 112. The metallic materials mentioned above could grow at room temperature and achieve good adhesion with Cu through metallic bonding. Because the metallic materials mentioned above have similar coefficients of thermal expansion to TaN, ALD TaN layer adhesion on these metallic materials is better than ALD TaN layer adhesion on Cu. Thus, with the third metal layer 122, less stress would be generated at the interface between the ALD TaN layer at the bottom of the via structure 118 and Cu in the first metal layer 106. The third metal layer 122 would help to eliminate voids at the interface and reduce the via resistance of the via structure 118. The interconnect structure 100 further comprises a second cap layer 124 on the second metal layer 116. As an example, the second cap layer 124 may comprise Co.

As mentioned above, according to certain aspects of the present disclosure, the combination of ALD TaN layer and PVD TaN layer at the bottom of the via structure 118 together with the third metal layer 122 would reduce the via resistance of the via structure 118 and improve the performance of the interconnect structure 100.

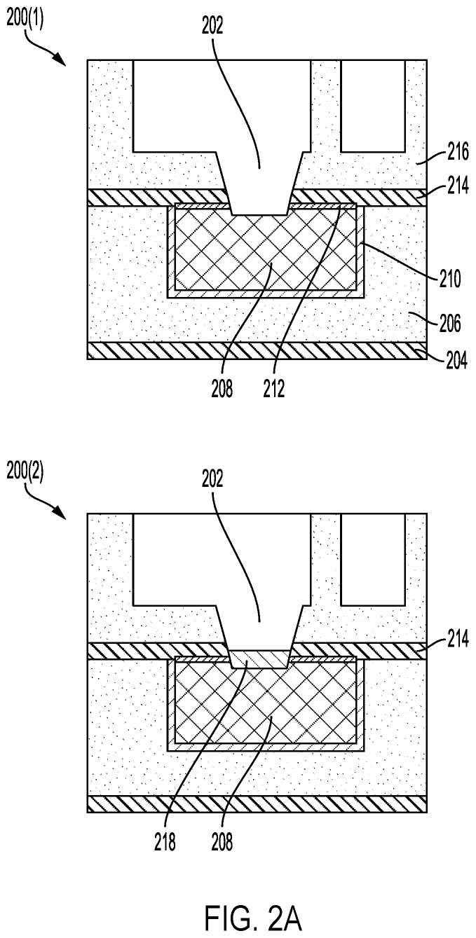

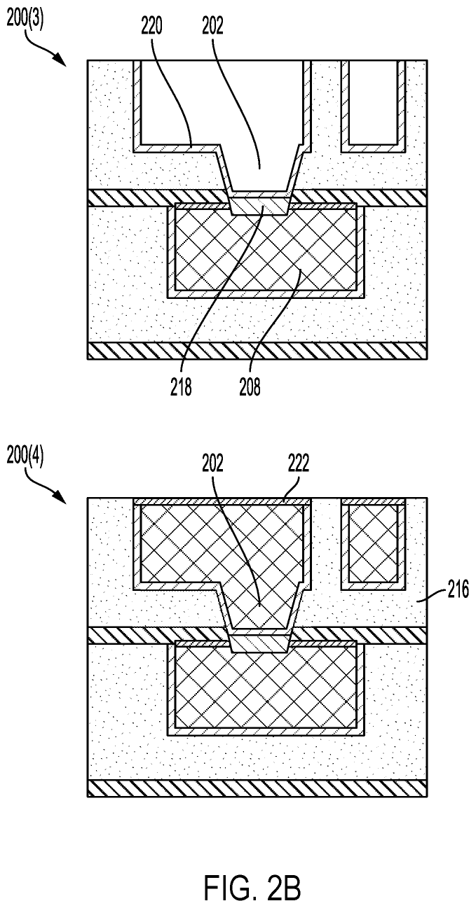

FIGS. 2A-2B illustrate an exemplary fabrication process for the interconnect structure 100 in FIG. 1 in accordance with certain aspects of the present disclosure. In FIG. 2A, stage 200(1) includes forming trench and via opening 202 in an interconnect structure of a semiconductor device. As an example, the interconnect structure may comprise a first etch stop layer 204. The first etch stop layer 204 may comprise at least one of SiCN and AN with ODC. The interconnect structure may also comprise a first dielectric layer 206 on the first etch stop layer 204. The first dielectric layer 206 may comprise SiCOH. The interconnect structure may also comprise a first metal layer 208 in the first dielectric layer 206. The first metal layer 208 may comprise Cu. The interconnect structure may also comprise a first barrier layer 210 between the first dielectric layer 206 and the first metal layer 208. The first barrier layer 210 may comprise a first TaN layer between the first dielectric layer 206 and the first metal layer 208 and a first Co liner between the first TaN layer and the first metal layer 208. The interconnect structure may also comprise a first cap layer 212 on the first metal layer 208. The first cap layer 212 may comprises Co. The interconnect structure may also comprise a second etch stop layer 214 on the first dielectric layer 206 and on the first cap layer 212. The second etch stop layer 214 may comprise at least one of SiCN and AN with ODC. The interconnect structure may further comprise a second dielectric layer 216 on the second etch stop layer 214. The second dielectric layer 216 may comprise SiCOH. The trench and via opening 202 is formed in the second dielectric layer 216 and through the second etch stop layer 214 and the first cap layer 212. The trench and via opening 202 extends into the first metal layer 208 to form a recess in the first metal layer 208. As an example, the trench and via opening 202 may be formed by a dual damascene process.

In FIG. 2A, stage 200(2) includes forming a second metal layer 218 on the first metal layer 208 at bottom of the trench and via opening 202. As an example, the second metal layer 218 may comprise a metallic material having a coefficient of thermal expansion less than 7×10⁻⁶/K, such as W, Mo, Cr, Os, Zr, Hf, Re, Ce, Ta, Ru, Ir, and Pr. The second metal layer 218 may have a thickness less than 5 nm. A top surface of the second metal layer 218 may be coplanar with or below a top surface of the second etch stop layer 214. As an example, the second metal layer 218 may be formed by selective deposition, such as electroless deposition at room temperature, and may achieve good adhesion with Cu in the first metal layer 208 through metallic bonding.

In FIG. 2B, stage 200(3) includes forming a second barrier layer 220 on sidewalls of the trench and via opening 202 and on the second metal layer 218. As an example, the second barrier layer 220 may comprise a second TaN layer on the sidewalls of the trench and via opening 202 and on the second metal layer 218 and a second Co liner on the second TaN layer. The second TaN layer may be formed by ALD TaN with a thickness between 11 A and 21 A followed by PVD TaN with a thickness between 5 A and 15 A on the sidewalls of the trench and via opening 202. Then, the second Co liner may be formed by Chemical Vapor Deposition (CVD) on the PVD TaN. The second Co liner may have a thickness between 20 A and 30 A.

As mentioned above, PVD is a non-conformal deposition process. A thickness of PVD TaN layer on the second metal layer 218 would be around twice a thickness of PVD TaN layer on the sidewalls of the trench and via opening 202. ALD is a conformal deposition process. A thickness of ALD TaN layer on the second metal layer 218 would be around the same as a thickness of ALD TaN layer on the sidewalls of the trench and via opening 202. A thickness of the second TaN layer on the second metal layer 218 would affect via resistance. A thinner second TaN layer on the second metal layer 218 would reduce the via resistance and improve performance of the interconnect structure. Meanwhile, PVD TaN layer has better adhesion to Co liners compared to ALD TaN layer. Thus, to realize both low via resistance and good adhesion to Co liners, a combination of ALD TaN and PVD TaN could be used to form the second TaN layer. Even though, ALD may be performed around 275° C., less stress would be generated at interface between the second TaN layer and the second metal layer 218, because the second metal layer 218 has similar coefficients of thermal expansion to TaN. The introduction of the second metal layer 218 between the second TaN layer and the first metal layer 208 would help to eliminate voids at the bottom of the trench and via opening 202 and reduce the via resistance. Thus, the performance of the interconnect structure would be improved.

In FIG. 2B, stage 200(4) includes depositing a third metal in the trench and via opening 202. As an example, the third metal may comprise Cu. Stage 200(4) also includes Chemical Mechanical Polishing (CMP) of the third metal and the second dielectric layer 216. Stage 200(4) further includes forming a second cap layer 222 on the third metal. As an example, the second cap layer 222 may comprise Co.

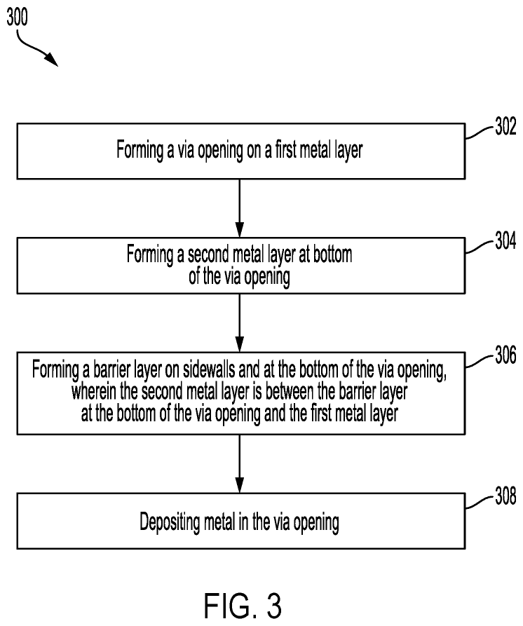

FIG. 3 shows a flow chart 300 illustrating an exemplary fabrication process for the interconnect structure 100 in FIG. 1. Block 302 includes forming a via opening on a first metal layer. Block 304 includes forming a second metal layer at bottom of the via opening. Block 306 includes forming a barrier layer on sidewalls and at the bottom of the via opening, wherein the second metal layer is between the barrier layer at the bottom of the via opening and the first metal layer. Block 308 includes depositing metal in the via opening to form the interconnect structure 100.

The interconnect structure comprising the low via resistance via structure according to certain aspects disclosed herein may be provided in or integrated into any electronic device. Examples, without limitation, include a set top box, an entertainment unit, a navigation device, a communication device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, and a drone.

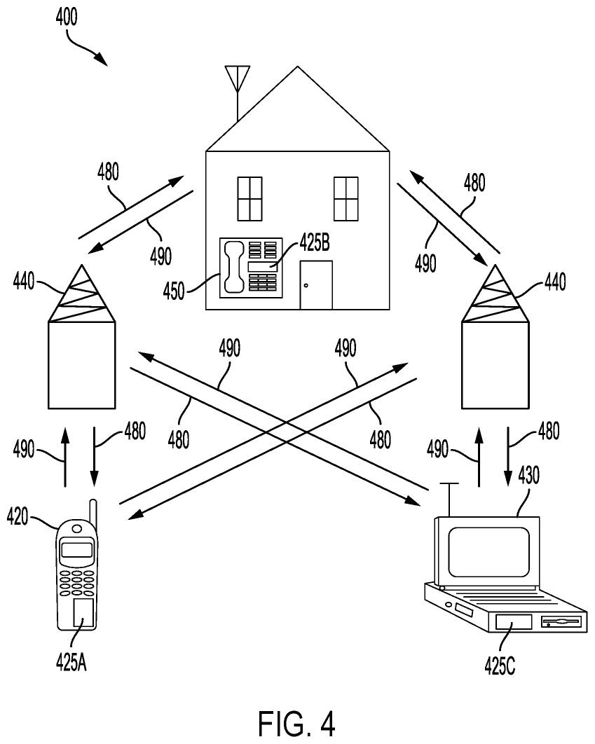

FIG. 4 is a block diagram showing an exemplary wireless communication system 400 in which an aspect of the present disclosure may be employed. For purposes of illustration, FIG. 4 shows three remote units 420, 430, and 450 and two base stations 440. It will be recognized that wireless communication systems may have many more remote units and base stations. Remote units 420, 430, and 450 include integrated circuit (IC) devices 425A, 425C, and 425B that may include the disclosed interconnect structure. It will be recognized that other devices may also include the disclosed interconnect structure, such as the base stations, switching devices, and network equipment. FIG. 4 shows forward link signals 480 from the base stations 440 to the remote units 420, 430, and 450 and reverse link signals 490 from the remote units 420, 430, and 450 to the base stations 440.

In FIG. 4, remote unit 420 is shown as a mobile telephone, remote unit 430 is shown as a portable computer, and remote unit 450 is shown as a fixed location remote unit in a wireless local loop system. For example, a remote unit may be a mobile phone, a hand-held personal communication systems (PCS) unit, a portable data unit such as a PDA, a GPS enabled device, a navigation device, a set top box, a music player, a video player, an entertainment unit, a fixed location data unit, such as a meter reading equipment, or other communication device that stores or retrieves data or computer instructions, or combinations thereof. Although FIG. 4 illustrates remote units according to certain aspects of the present disclosure, the present disclosure is not limited to these exemplary illustrated units. Certain aspects of the present disclosure may be suitably employed in many devices, which include the disclosed interconnect structure.

Implementation examples are described in the following numbered clauses:

Clause 1: An interconnect structure of a semiconductor device, the interconnect structure comprising: a via structure, the via structure comprising a barrier layer on sidewalls and at bottom of the via structure; a first metal layer; and a second metal layer between the barrier layer at the bottom of the via structure and the first metal layer, wherein the first metal layer and the second metal layer comprise different materials.

Clause 2: The interconnect structure of clause 1, wherein the barrier layer comprises Tantalum Nitride (TaN) and Cobalt (Co).

Clause 3: The interconnect structure of clause 1 or clause 2, wherein the first metal layer comprises Copper (Cu).

Clause 4: The interconnect structure of any of clauses 1 to 3, wherein the second metal layer comprises a metallic material having a coefficient of thermal expansion less than 7×10⁻⁶/K.

Clause 5: The interconnect structure of clause 4, wherein the metallic material comprises at least one of Tungsten (W), Molybdenum (Mo), Chromium (Cr), and Ruthenium (Ru).

Clause 6: The interconnect structure of any of clauses 1 to 5, wherein the second metal layer has a thickness less than 5 nanometer.

Clause 7: The interconnect structure of any of clauses 1 to 6, further comprising a cap layer on the first metal layer.

Clause 8: The interconnect structure of clause 7, wherein the cap layer comprises Co.

Clause 9: The interconnect structure of clause 7 or clause 8, further comprising an etch stop layer on the cap layer.

Clause 10: The interconnect structure of clause 9, wherein a top surface of the second metal layer is coplanar with or below a top surface of the etch stop layer.

Clause 11: The interconnect structure of clause 9 or clause 10, wherein the etch stop layer comprises at least one of Silicon Carbon Nitride (SiCN) and Aluminum Nitride (AlN) with Oxygen Doped Carbon (ODC).

Clause 12: A method for fabricating an interconnect structure of a semiconductor device, the method comprising: forming a via opening on a first metal layer; forming a second metal layer at bottom of the via opening, wherein the first metal layer and the second metal layer comprise different materials; forming a barrier layer on sidewalls and at the bottom of the via opening, wherein the second metal layer is between the barrier layer at the bottom of the via opening and the first metal layer; and depositing metal in the via opening.

Clause 13: The method of clause 12, wherein the barrier layer comprises Tantalum Nitride (TaN) and Cobalt (Co).

Clause 14: The method of clause 13, wherein the TaN in the barrier layer comprises TaN formed by Atomic Layer Deposition (ALD) and Physical Vapor Deposition (PVD).

Clause 15: The method of any of clauses 12 to 14, wherein the first metal layer comprises Copper (Cu).

Clause 16: The method of any of clauses 12 to 15, wherein the second metal layer comprises a metallic material having a coefficient of thermal expansion less than 7×10⁻⁶/K.

Clause 17: The method of clause 16, wherein the metallic material comprises at least one of Tungsten (W), Molybdenum (Mo), Chromium (Cr), and Ruthenium (Ru).

Clause 18: The method of any of clauses 12 to 17, wherein the second metal layer is formed by electroless deposition.

Clause 19: The method of any of clauses 12 to 18, further comprising forming a cap layer on the metal in the via opening.

Clause 20: The method of clause 19, wherein the cap layer comprises Co.

Those of skill in the art will further appreciate that the various illustrative logical blocks, modules, circuits, and algorithms described in connection with certain aspects disclosed herein may be implemented as electronic hardware, instructions stored in memory or in another computer readable medium and executed by a processor or other processing device, or combinations of both. The devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in any flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and features disclosed herein.

What is claimed is:

1. An interconnect structure of a semiconductor device, the interconnect structure comprising:
a via structure, the via structure comprising a barrier layer on sidewalls and at bottom of the via structure;
a first metal layer; and
a second metal layer between the barrier layer at the bottom of the via structure and the first metal layer, wherein the first metal layer and the second metal layer comprise different materials.

2. The interconnect structure of claim 1, wherein the barrier layer comprises Tantalum Nitride (TaN) and Cobalt (Co).

3. The interconnect structure of claim 1, wherein the first metal layer comprises Copper (Cu).

4. The interconnect structure of claim 1, wherein the second metal layer comprises a metallic material having a coefficient of thermal expansion less than 7×10⁻⁶/K.

5. The interconnect structure of claim 4, wherein the metallic material comprises at least one of Tungsten (W), Molybdenum (Mo), Chromium (Cr), and Ruthenium (Ru).

6. The interconnect structure of claim 1, wherein the second metal layer has a thickness less than 5 nanometer.

7. The interconnect structure of claim 1, further comprising a cap layer on the first metal layer.

8. The interconnect structure of claim 7, wherein the cap layer comprises Co.

9. The interconnect structure of claim 7, further comprising an etch stop layer on the cap layer.

10. The interconnect structure of claim 9, wherein a top surface of the second metal layer is coplanar with or below a top surface of the etch stop layer.

11. The interconnect structure of claim 9, wherein the etch stop layer comprises at least one of Silicon Carbon Nitride (SiCN) and Aluminum Nitride (AlN) with Oxygen Doped Carbon (ODC).

12. A method for fabricating an interconnect structure of a semiconductor device, the method comprising:
forming a via opening on a first metal layer;
forming a second metal layer at bottom of the via opening, wherein the first metal layer and the second metal layer comprise different materials;
forming a barrier layer on sidewalls and at the bottom of the via opening, wherein the second metal layer is between the barrier layer at the bottom of the via opening and the first metal layer; and
depositing metal in the via opening.

13. The method of claim 12, wherein the barrier layer comprises Tantalum Nitride (TaN) and Cobalt (Co).

14. The method of claim 13, wherein the TaN in the barrier layer comprises TaN formed by Atomic Layer Deposition (ALD) and Physical Vapor Deposition (PVD).

15. The method of claim 12, wherein the first metal layer comprises Copper (Cu).

16. The method of claim 12, wherein the second metal layer comprises a metallic material having a coefficient of thermal expansion less than 7×10⁻⁶/K.

17. The method of claim 16, wherein the metallic material comprises at least one of Tungsten (W), Molybdenum (Mo), Chromium (Cr), and Ruthenium (Ru).

18. The method of claim 12, wherein the second metal layer is formed by electroless deposition.

19. The method of claim 12, further comprising forming a cap layer on the metal in the via opening.

20. The method of claim 19, wherein the cap layer comprises Co.
